(19) United States
(12) Patent Application Publication
(10) Pub. No.: US 2002/0093288 A1
(43) Pub. Date: Jul. 18, 2002

(54) IMAGING APPARATUS

(76) Inventors: SIMON H. SPENCER, DANBURY (GB); IAN C. PALMER, BRENTWOOD (GB)

Correspondence Address: VENABLE, P O BOX 34385, WASHINGTON, DC, 200439998

(21) Appl. No.: 09/469,751

(22) Filed: Dec. 22, 1999

(30) Foreign Application Priority Data
Dec. 22, 1998 (GB) GB 9828166.0

(51) Int. Cl. H01L 27/00

(52) U.S. Cl. 313/523

(57) ABSTRACT

Imaging apparatus suitable for photon counting applications or low light imaging includes a CCD sensor 4 arranged to receive electrons emitted from a photocathode 1. The CCD sensor includes a separate multiplication register into which signal charge from its output register is transferred to give improved noise performance and resolution.

This invention relates to imaging apparatus and more particularly to apparatus which includes a CCD (charge coupled device) sensor.

A requirement exists for low light level imaging and/or for position sensitive photon counting. One method of imaging low light level scenes involves using an image intensifier in front of a CCD sensor. Amplification of the electron signal occurs in a microchannel plate (MCP) included in the image intensifier. The use of the MCP enables resolution to be maintained to a satisfactory quality but introduces a high noise factor into the system. The gain mechanism associated with the MCP means that it has a broad pulse height distribution and it is not possible to use a single MCP image intensifier for photon counting applications.

An alternative device manufactured by placing the CCD inside the vacuum envelope of a photocathode, for direct imaging of the photocathode, has also been used for low light imaging (termed the Electron Bombarded CCD or EBCCD). This has the advantage of removing the MCP and so improving both the signal to noise ratio and the resolution. However, when operating at normal TV frame rates (50 or 60 Hz) the output noise is still sufficiently large that it will be the dominant noise source at the very lowest light levels. This also means that it is only possible to use the EBCCD for photon counting applications where the frame rate is reduced from that required for TV imaging sufficiently to reduce the device output noise.

For applications where photon counting is required the imaging method has frequently been to use either a very thick MCP or several MCPs in series arranged so that the gain within the MCP is saturated which gives a narrow pulse height distribution, enabling each event to be separately detected The multiple MCP image intensifier is then read out through a CCD in the normal way. The multi MCP Image Intensifier can effectively photon count. However it is very sensitive to damage from light overload and so has not been widely used.

All of the alternatives described above have serious disadvantages for photon counting or at the lowest light levels as described above.

According to the invention, there is provided an imaging apparatus comprising a photocathode which emits electrons representative of incident radiation to which it is sensitive, and a CCD sensor which includes an image area, an output register which receives signal charge from the image area, a separate multiplication register into which signal charge from the output register is transferred, and means for obtaining signal charge multiplication by transferring the charge through a sufficiently high field in elements of the multiplication register, the CCD sensor being arranged to receive electrons generated at the photocathode in response to incident radiation.

The photocathode is preferably closely spaced from the CCD sensor inside a vacuum envelope to provide proximity focussing to give good resolution. There is no need for the MCP and phosphor screen required for an intensified CCD arrangement and thus resolution of apparatus in accordance with the invention will tend to be better in comparison.

The photocathode may be, for example, of gallium arsenide, but a number of photocathode materials and types are available which may be used to extend the optical bandwidth over which the apparatus is capable of being used. For example, multi-alkali photocathodes such as S20, bi-alkali and S25 may be used, solar blind photocathodes such as CsTe, or for example transferred electron photocathodes (InGaAs) for operation from 0.9 microns to 1.7 microns incident radiation wavelength.

The CCD sensor is such that additional gain is added to the signal from the CCD image area before an output amplifier stage is reached. The effect of readout noise is reduced by this gain factor, enabling the CCD sensor to be used for low light imaging. It is believed that gain factors approaching 1,000 may be possible for the CCD sensor alone when operated to image directly without a photocathode. In combination with the photocathode to provide electron bombardment of the CCD sensor, it is possible for photon counting to be carried out in such a way that photon discrimination will be possible. A CCD sensor suitable for use in the present invention is described in our co-pending European application, publication serial number EP 0 866 501 A.

The main advantage of this invention over the standard EBCCD is that the signal from a single electron emitted from the photocathode is amplified by a sufficient factor that it may be detected above the output noise. Thus for example if the camera/device output noise is 150 to 200 electrons equivalent signal (standard deviation) the signal produced in the CCD by the action of the high energy electron impact is approximately 200 electrons making it indistinguishable from the noise. In order to detect an event in the signal should be at least 6 times the standard deviation. This means that if the amplification register is operated at say a gain of ×20 the signal may be unambiguously detected above the noise. This ability to detect single electrons means that this device will give the best possible performance at the lowest light levels. Alternatively the device may be used in photon counting applications at TV frame rates. The advantage of this invention over the image intensifier is that the MCP is eliminated thus improving the noise and resolution. The standard image intensifier is also not useable for photon counting. This device also has a significant advantage over the multiple MCP Image Intensifier which has a very limited life especially when subject to even modest light overload. The Multi MCP Image Intensifier will also suffer from the same problems associated with the MCPs as the standard device such as loss of resolution and the introduction of image artifacts.

Preferably, means are provided for gating on and off a photocathode to CCD sensor accelerating voltage. This enables the apparatus to be used, for example, for range gating and time delayed fluorescence monitoring.

The CCD sensor may be one manufactured for TV imaging such as 525, 625 and 875 line formats. Alternatively, a scientific CCD sensor may be used with non-CCIR or RS170 formats.

One way in which the invention may be performed is now described, by way of example, with reference to the accompanying drawings, in which:

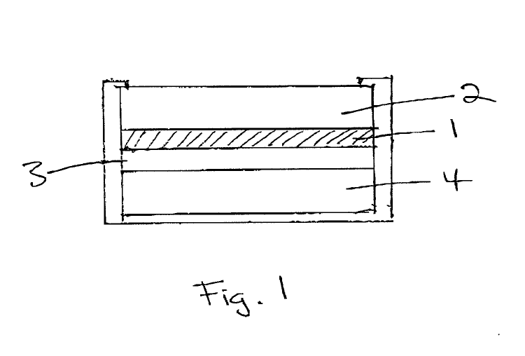

FIG. 1 schematically illustrates imaging apparatus in accordance with the invention; and

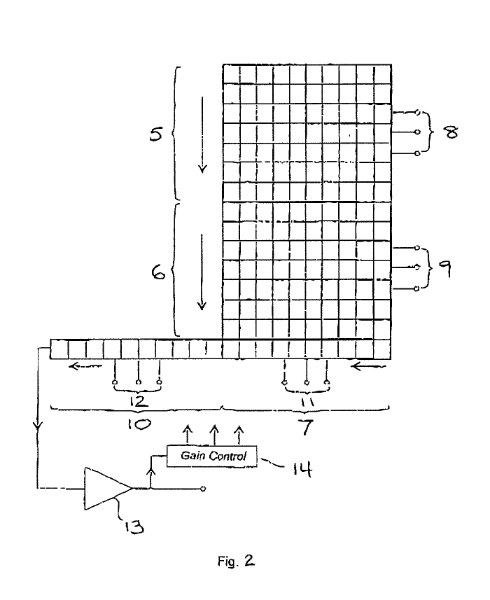

FIG. 2 schematically shows the CCD sensor of the apparatus shown in FIG. 1.

With reference to FIG. 1, an imaging apparatus in accordance with the invention comprises a photocathode layer 1, which in this embodiment is of gallium arsenide, which is deposited on a glass substrate 2 contained within a vacuum envelope 3. A silicon CCD sensor 4 is closely spaced from the photocathode 1 to provide proximity focussing. An accelerating voltage is applied between the photocathode 1 and the CCD sensor 4 in the region of 1.4 kV to 2 kV. This may be gated on and off if required. The photocathode 1 absorbs any incident photons to which it is sensitive and converts them into electrons. Some of the electrons generated by the incident photons reach the vacuum interface between the photocathode 1 and the CCD sensor 4 and are accelerated towards and into the pixels of the silicon CCD 4.

Allowing for energy losses at the input surface of the CCD an acceleration voltage of 1.4 kV to 2 kV creates a total of about 150 to 200 electron-hole pairs for each primary electron

With reference to FIG. 2, charge is accumulated in pixels of an image area 5 and is subsequently transferred to a store section 6 and then on a row-by-row basis to an output register 7 by applying suitable drive pulses to electrodes 8 and 9. Signal charge in the output register 7 is transferred to a multiplication register 10 by drive pulses applied to electrodes 11 and 12 to give charge transfer in the direction shown by the arrows. One or more drive pulses applied to the electrodes of the multiplication register 10 are of sufficiently large amplitude to produce high field regions in the register element to cause signal multiplication by impact ionisation. This gives a low noise amplification of the signal charge, the multiplied signal charge being detected at a charge detection circuit 13. Gain control circuit 14 may be used to adjust the operation of the imaging apparatus.

The electron bombardment gain of the CCD sensor adds very little noise to the signal, resulting in a noise factor of 1.1 which, in combination with the on-chip gain of the CCD sensor, is sufficient for photon counting to be carried out in such a way that photon discrimination will be possible.

1. An imaging apparatus comprising a photocathode which emits electrons representative of incident radiation to which it is sensitive, and a CCD sensor which includes an image area, an output register which receives signal charge from the image area, a separate multiplication register into which signal charge from the output register is transferred, and means for obtaining signal charge multiplication by transferring the charge through a sufficiently high field in elements of the multiplication register, the CCD sensor being arranged to receive electrons generated at the photocathode in response to incident radiation.

2. Apparatus as claimed in claim 1 wherein the photocathode is closely spaced from the CCD) sensor to provide proximity focussing.

3. Apparatus as claimed in claim 1 or 2 and including means for gating on and off an accelerating voltage between the photocathode and CCD sensor.

4. Apparatus as claimed in claim 1, 2 or 3 wherein the multiplication is such that a single electron emitted from the photocathode is detectable.

5. Apparatus as claimed in claim 1, 2 or 3 wherein the CCD sensor is operated at TV frame rates and to provide photon counting.

6. Imaging apparatus substantially as illustrated in and described with reference to the accompanying drawings.
